(19) United States
(12) Patent Application Publication
(10) Pub. No.: US 2007/0004139 A1
(43) Pub. Date: Jan. 4, 2007

(54) Method of manufacturing a non-volatile semiconductor device

(76) Inventors: Hong-Gun Kim, Suwon-si (KR); Kyu-Tae Na, Seoul (KR); Eun-Kyung Baek, Suwon-si (KR); Ju-Seon Goo, Suwon-si (KR); Sang-Ho Rha, Seoul (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/474,428

(22) Filed: Jun. 26, 2006

(30) Foreign Application Priority Data
Jun. 30, 2005 (KR) 2005-58425

(51) Int. Cl. H01L 21/336

(52) U.S. Cl. 438/257

(57) ABSTRACT

In a method of manufacturing a non-volatile semiconductor device, a mask structure is formed on a substrate. A trench is formed by partially etching the substrate using the mask structure. A preliminary isolation layer pattern is formed on the substrate to fill the trench. The preliminary isolation layer has an upper face lower than that of the mask structure. A capping layer pattern is formed on the preliminary isolation layer pattern. An opening and an isolation layer pattern are formed by removing the mask structure and a portion on a sidewall of the preliminary isolation layer pattern adjacent to the mask structure. After forming a tunnel oxide layer, a floating gate is formed on the tunnel oxide layer and a sidewall of the isolation layer pattern.

### BACKGROUND OF THE INVENTION

1. Field of the Invention

Embodiments of the present invention relate to a method of manufacturing a non-volatile semiconductor device. More particularly, embodiments of the present invention relate to a method of manufacturing a non-volatile semiconductor device having a floating gate formed through a self-aligned polysilicon (SAP) process.

This application claims priority to Korean Patent Application No. 2005-58425 filed on Jun. 30, 2005, the subject matter of which is hereby incorporated by reference.

2. Description of the Related Art

The development of contemporary semiconductor devices is characterized by constant efforts to reduce the sizes of individual devices in order to increase integration density. This trend continues in the development of non-volatile semiconductor memory devices, such as flash memory devices. In order to significantly reduce the overall size of a flash memory device, the size of its floating gate must be addressed. Thus, the size and position of the floating gate in the flash memory device becomes a critical design parameter that must be carefully controlled. For example, as the size of the floating gate decreases, the risk of an alignment error in an etching process used to form the floating gate may increase. Such an alignment error will reduce the coupling ratio for the flash memory device.

Fabricating flash memory devices with greater integration density leads to other problems as well. For example, a void or a seam may be formed in an isolation layer commonly used to fill trench structures in contemporary flash memory devices which have high aspect ratios. Such voids or seams greatly deteriorate the electrical characteristics of the flash memory device because the isolation region formed by the trench structures are already much reduced in size and therefore provide electrical isolation with minimal tolerance for error.

Several methods have previously been proposed to address the issues of proper floating gate formation in conventional flash memory devices. One such method is referred to as a self-aligned polysilicon (SAP) process. The SAP process reduces the possibility of alignment errors being generated during the formation of the floating gate. For example, U.S. Pat. No. 6,465,293, the subject matter of which is hereby incorporated by reference, discloses a method of manufacturing a flash memory cell using an SAP process. In this conventional method, an isolation layer is formed on a semiconductor substrate, and then an oxide layer is formed on the isolation layer. An oxide layer pattern exposing a portion of the substrate is then formed by etching the oxide layer. A tunnel oxide layer and a first polysilicon layer are sequentially formed on the oxide layer pattern and the exposed portion of the substrate. The first polysilicon layer is partially removed until the tunnel oxide layer is exposed to thereby form the floating gate on the exposed portion of the substrate. After the exposed portions of the tunnel oxide layer and the oxide layer pattern are partially removed, a dielectric layer is formed on the resultant structure. After a second polysilicon layer and a tungsten silicide layer are formed on the dielectric layer, the second polysilicon layer and the tungsten silicide layer are etched to form the floating gate on the dielectric layer. When impurity regions are formed in portions of the substrate adjacent to the floating gate, the flash memory device is complete.

In the above method of forming the conventional flash memory device, the isolation layer includes silicon oxide formed by a spin on glass coating process so that the isolation layer effectively fills up the trench without a void or a seam. When the floating gate is formed through the SAP process, the isolation layer may be formed with a precisely controlled structure during the formation of the floating gate because the isolation layer serves as a mold pattern. Thus, the isolation layer should have a dense structure able to endure subsequently applied etching processes and/or polishing processes necessary to the ultimate formation of the floating gate. However, when the isolation layer is formed by the spin on glass coating process, it may not have the desired dense structure. So, the isolation layer may be excessively etched during subsequently applied etching processes and/or the polishing processes.

In a case where excessive recesses are generated in the isolation layer, the isolation layer will have an upper face profile that is lower than that of the substrate, such that the isolation layer may not electrically isolate adjacent unit cells of the flash memory device. Additionally, stepped portions of the isolation layer may be disadvantageously generated by excessively etching. As a result, the floating gate formed using the isolation layer as the mold pattern may not have the desired height and/or a desired uniform thickness. Such variations among floating gates formed across a great plurality of unit cells will adversely affect performance of the flash memory device.

### SUMMARY OF THE INVENTION

Embodiments of the present invention provide a method of manufacturing a non-volatile semiconductor device including a floating gate that has a well controlled thickness without generating a recess in an associated isolation layer.

Thus, in one example embodiment, the present invention provides a method of manufacturing a non-volatile semiconductor device, comprising; forming a mask structure including a pad oxide layer pattern and a hard mask pattern sequentially formed on a substrate, selectively etching the substrate using the mask structure as an etching mask to form a trench in the substrate, forming a preliminary isolation layer pattern on the substrate to fill the trench, wherein the preliminary isolation layer pattern has an upper face substantially lower than an upper face of the mask structure, forming a capping layer pattern on the preliminary isolation layer pattern, forming an opening and an isolation layer pattern by removing the mask structure and a portion on a sidewall of the preliminary isolation layer pattern making contact with the mask structure, forming a tunnel oxide layer on a portion of the substrate exposed by the opening, and forming a floating gate on the tunnel oxide layer and a sidewall of the isolation layer pattern.

### BRIEF DESCRIPTION OF THE DRAWINGS

Embodiments of the present invention will be described with reference to the accompanying drawings in which:

FIGS. 1 to 11 are cross-sectional views illustrating a method of manufacturing a non-volatile semiconductor device in accordance with example embodiments of the present invention; and

FIGS. 12 to 14 are cross-sectional views illustrating a method of manufacturing a non-volatile semiconductor device in accordance with example embodiments of the present invention.

### DESCRIPTION OF EMBODIMENTS

The present invention is described more fully hereinafter with reference to the accompanying drawings, in which example embodiments are shown. The present invention may, however, be embodied in many different forms and should not be construed as being limited to only the embodiments set forth herein. Rather, these embodiments are presented as teaching examples. In the drawings, the sizes and relative sizes of layers and regions may be exaggerated for clarity. Throughout the drawings and written description, like numbers refer to like or similar elements.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section.

Spatially relative terms, such as “beneath,” “below,” “lower,” “above,” “upper” and the like, may be used herein for ease of description to describe one element or feature's relationship to another element(s) or feature(s) as illustrated in the drawings. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the present invention are described herein with reference to cross-sectional illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In a method of manufacturing a non-volatile semiconductor device according to certain embodiments of the invention, mask structures may be formed on a substrate such as a silicon wafer or a silicon-on-insulator (SOI) substrate. Each of the mask structures may include a pad oxide layer pattern and a hard mask pattern sequentially formed on the substrate.

A preliminary isolation layer pattern may be formed on the substrate. The preliminary isolation layer pattern may partially cover an upper portion of the substrate between the mask structures. The preliminary isolation layer pattern may have an upper face substantially lower than upper faces of the mask structures. The preliminary isolation layer pattern may have a line shape extending along a first direction on the substrate. The preliminary isolation layer pattern may have a multi-layer structure that includes a first insulation layer pattern and a second insulation layer pattern. The first insulation layer pattern may prevent a sidewall of the preliminary isolation layer pattern from being excessively etched in subsequent etching processes. The second insulation layer pattern may electrically isolate a unit cell of the non-volatile semiconductor device from an adjacent unit cell of the non-volatile semiconductor device.

While forming the preliminary isolation layer pattern, the substrate may be partially etched using the mask structure as an etching mask to form a trench at the upper portion of the substrate. After a first insulation layer may be continuously formed on a sidewall and a bottom of the trench and on the mask structure, a second insulation layer may be formed on the first insulation layer to fill up the trench. The first insulation layer may be formed using a material that has an etching rate substantially lower than an etching rate of a material in the second insulation layer (not shown) during an etching process using a predetermined etching solution or a predetermined etching gas. For example, the second insulation layer may be formed using second silicon oxide prepared through a spin on glass process so as to effectively fill up the trench. Additionally, the first insulation layer may be formed using first silicon oxide prepared by a thermal chemical vapor deposition (CVD) process. Alternatively, the first insulation layer may be formed using first silicon oxide prepared through a high density plasma-chemical vapor deposition (HDP-CVD) process. Then, the first and the second insulation layers may be partially removed until the mask structures are exposed to thereby form a preliminary first insulation layer pattern and a preliminary second insulation layer pattern. The first and the second insulation layers may be partially removed by a chemical mechanical polishing (CMP) process. When upper portions of the preliminary first and preliminary second insulation layer patterns are etched, the preliminary isolation layer pattern may be formed on the substrate to fill up the trench.

After a capping layer may be formed on the preliminary isolation layer pattern and the mask structure, a portion of the capping layer positioned on the mask structure may be selectively removed, thereby forming a capping layer pattern on the preliminary isolation layer pattern. The capping layer may be formed using polysilicon. The capping layer may be partially removed through a CMP process. The capping layer may have a thickness in a range of about 50 Å to about 5,000 Å.

A portion on a sidewall of the preliminary isolation layer pattern adjacent to the mask structure may be removed together with the mask structure. Hence, an opening and an isolation layer pattern may be formed. The opening may expose a portion of the substrate adjacent to the isolation layer pattern. When the portion on the sidewall of the preliminary isolation layer pattern is removed, a portion of the first insulation layer pattern may be selectively removed.

After a tunnel oxide layer may be formed on the exposed portion of the substrate, a floating gate may be formed on the tunnel oxide layer to fill up the opening.

In one example embodiment of the present invention adapted to the formation of the floating gate, a first conductive layer may be continuously formed on a sidewall of the opening, on the tunnel oxide layer and on the capping layer pattern. A sacrificial layer may be formed on the first conductive layer to fully fill up the opening, and then the sacrificial layer, the first conductive layer and the capping layer pattern may be partially etched, thereby forming the floating gate on the substrate.

In another example embodiment of the present invention adapted to the formation of the floating gate, a first conductive layer may be formed on the tunnel oxide layer to completely fill up the opening. Then, the first conductive layer and the capping layer pattern may be partially etched until the isolation layer pattern is exposed so that the floating gate may be formed on the substrate.

A dielectric layer and a control gate may be sequentially formed on the floating gate to form the non-volatile semiconductor device on the substrate.

According to certain embodiments of the invention, the isolation layer pattern may be effectively protected during successive etching, cleaning and/or polishing processes because the capping layer pattern may be positioned on the isolation layer pattern. That is, the isolation layer pattern may have a desired height for the floating gate and a uniform thickness from an upper face of the substrate. As a result, the non-volatile semiconductor device may have the floating gate of a desired height and improved electrical characteristics. When the floating gate may be formed through a self-aligned polysilicon (SAP) process that utilizes the isolation layer pattern as a mold pattern for forming the floating gate, the floating gate may have the desired height and a uniform thickness.

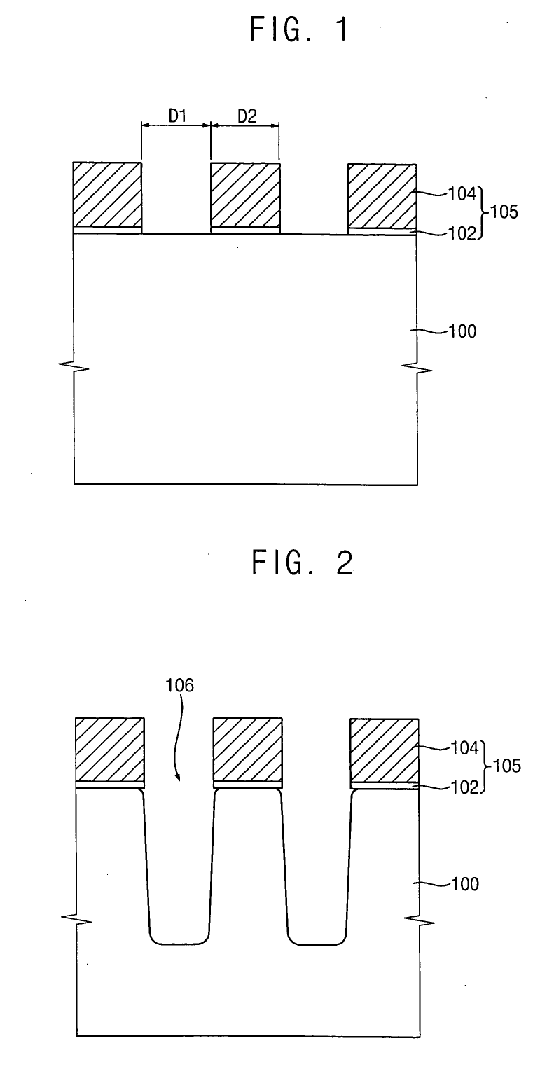

FIGS. 1 to 11 are cross-sectional views illustrating a method of manufacturing a non-volatile semiconductor device in accordance with example embodiments of the present invention.

Referring to FIG. 1, a pad oxide layer is formed on a semiconductor substrate 100 such as a silicon wafer or an SOI substrate. The pad oxide layer may be formed by a thermal oxidation process wherein a part of an upper portion of the substrate 100 may be thermally oxidized under an atmosphere including oxygen. Alternatively, the pad oxide layer may be formed on the substrate 100 by a CVD process. The pad oxide layer may have a thickness of about 10 Å to about 100 Å measured from the upper face of the substrate 100. The pad oxide layer may reduce a stress generated between the substrate 100 and a hard mask layer successively formed on the pad oxide layer by preventing the hard mask layer from directly making contact with the substrate 100.

The hard mask layer is formed on the pad oxide layer. The hard mask layer may be formed using a nitride such as silicon nitride. The hard mask layer is etched to form a first hard mask pattern 104 that serves as an etching mask for forming a trench 106 (see FIG. 2) at the upper portion of the substrate 100. Additionally, a floating gate 118b (see FIG. 11) will be formed over a portion of the substrate 100 where the first hard mask pattern 104 is positioned. The hard mask layer may advantageously have a sufficient thickness substantially greater than a desired height of the floating gate 118b because the hard mask layer may be consumed in successive etching and/or polishing processes. For example, the hard mask layer may have a sufficient thickness greater than the desired height of the floating gate 118b by about 100 Å to about 3,000 Å.

After a photoresist pattern (not shown) is formed on the hard mask layer, the hard mask layer and the pad oxide layer are sequentially etched using the photoresist pattern as an etching mask. Hence, mask structures 105 exposing portions of the substrate 100 are formed on the substrate 100. Each of the mask structures 105 includes a pad oxide layer pattern 102 and the first hard mask pattern 104 sequentially formed on the substrate 100.

In an example embodiment of the present invention, the mask structures 105 may have line shapes that extend along a first direction on the substrate 100. Each of the mask structures 105 may have a width D2 substantially the same as an interval D1 between adjacent mask structures 105.

Referring to FIG. 2, the exposed portion of the substrate 100 through the mask structure 105 is partially etched using the mask structure 105 as an etching mask. Thus, the trench 106 is formed at the upper portion of the substrate 100. The trench 106 may have a minute width below about 90 nm.

In an example embodiment of the present invention, a sidewall oxide layer (not shown) may be formed on a sidewall of the trench 106 and a portion of the substrate 100 exposed through the trench 106. The sidewall oxide layer may restore etched damages to the substrate 100 caused by the etching process for forming the trench 106. Additionally, the sidewall oxide layer may reduce a leakage current passing through the trench 106. The sidewall oxide layer may be formed by oxidizing the portion of the substrate 100 corresponding to the sidewall of the trench 106. Thus, the sidewall oxide layer may not be formed on the mask structure 105. However, the formation of the sidewall oxide layer may be omitted to simplify the manufacturing processes for forming the non-volatile semiconductor device.

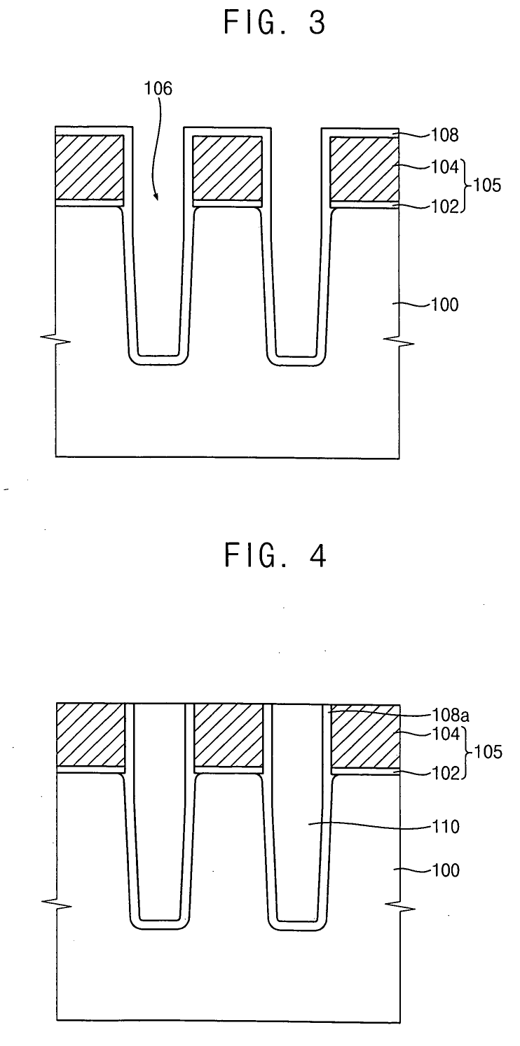

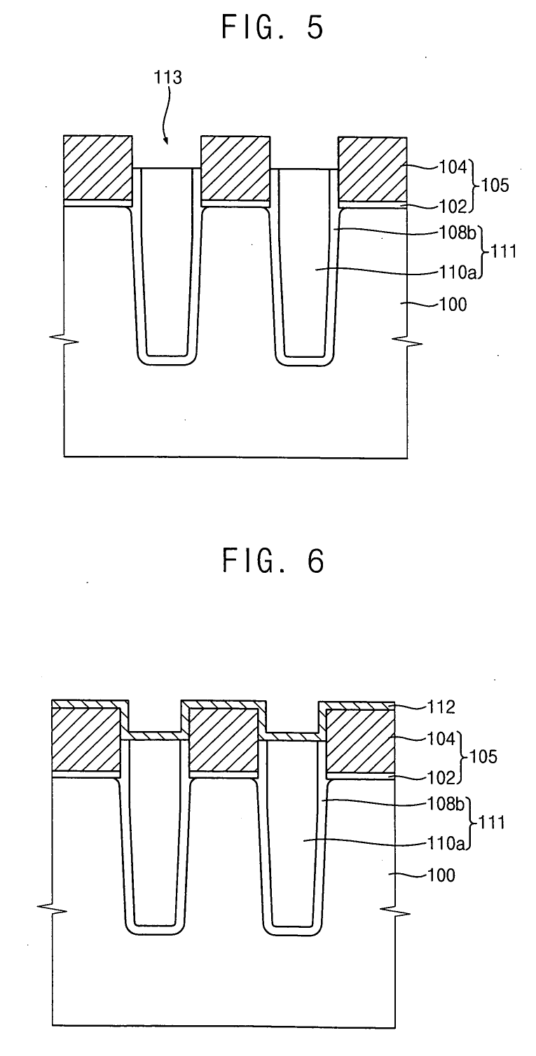

Referring to FIG. 3, a first insulation layer 108 is continuously formed on the sidewall and a bottom of the trench 106 and on the mask structure 105. The first insulation layer 108 may effectively protect the substrate 100 and a preliminary isolation layer pattern 111 (see FIG. 5) that fills up the trench 106 during subsequent etching processes. The first insulation layer 108 may be formed using a material that has a dense crystalline structure so that the first insulation layer 108 may not be easily etched in subsequent etching, cleaning and/or polishing processes.

In an example embodiment of the present invention, the first insulation layer 108 may have an etching rate substantially lower than that of a second insulation layer filling up the trench 106 when the first insulation layer 108 and the second insulation layer are etched using a predetermined etching solution or an etching gas. For example, the first insulation layer 108 may be formed using first silicon oxide prepared by a CVD process. Alternatively, the first insulation layer 108 may be formed using a first silicon oxide prepared through an HDP-CVD process, i.e., HDP-CVD oxide.

The first insulation layer 108 may have a sufficient thickness so that the first insulation layer 108 may partially remain after an etching process for etching the pad oxide layer pattern 102. In the etching process for removing the pad oxide layer pattern 102, the first insulation layer 108 may be partially etched so that second opening 114 (see FIG. 8) for forming the floating gate 118b may have a width substantially greater than the width D2 of the mask structure 105. However, an isolation layer pattern 111a (see FIG. 8) may have reduced a width when the width of the second opening 114 may be undesirably enlarged. As for a non-volatile semiconductor device having a design rule below about 90 nm, the second opening 114 may have a width greater than the width D2 of the mask structure 105 by about 70 Å to about 150 Å after removing the pad oxide layer pattern 102 from the substrate 100.

When the second opening 114 has the width substantially greater than the width D2 of the mask structure 105 by about 70 Å to about 150 Å according to adjusting the thickness of the first insulation layer 108, the first insulation layer 108 may have a thickness above about 35 Å. In some example embodiments of the present invention, the first insulation layer 108 may have a thickness in a range of about 100 Å to about 200 Å.

Referring to FIG. 4, the second insulation layer (not shown) is formed on the first insulation layer 108 to fill up the trench 106.

Since the trench 106 has the narrow width below about 90 nm and also the first insulation layer 108 is formed on the sidewall of the trench 106, a void or a seam may be generated in the trench 106 in case that the second insulation layer does not fully fill up the trench 106. Therefore, the second insulation layer is formed using a material that effectively fills up the trench 106 without generating the void or the seam therein. For example, the second insulation layer may be formed using second silicon oxide prepared through a spin on glass (SOG) process. That is, the second insulation layer may be formed using SOG.

Hereinafter, an exemplary process adapted to form the second insulation layer (not shown) will be described in some additional detail.

At first, SOG is coated on the first insulation layer 108 to fill up the trench 106. SOG may be coated on the first isolation layer 108 by a spin coating process. The coated SOG is thermally treated to form a silicon oxide layer on the first insulation layer 108. The silicon oxide layer corresponds to the second insulation layer (not shown). Examples of SOG include a siloxane-based material, a silanol-based material, a polysilazane-based material, etc. Here, the siloxane-based material includes —(HSiO0.5)n— as a building block and the silanol-based material includes —(SiOH)n— as a building block. Additionally, the polysilazane-based material includes —(SiH2NH2)n— as a building block.

When the silicon oxide layer is formed using the siloxane-based material, hydrogen may be separated so as to change the siloxane-based material into silicon oxide because the siloxane-based material has silicon-oxygen bonds (Si—O). Alternatively, hydrogen contained in the siloxane-based material may be substituted with other elements in order to convert the siloxane-based material into silicon oxide.

When the silicon oxide layer is formed using the silanol-based material, the silanol-based material includes silicon-hydroxyl bonds (Si—OH), silicon-oxygen bonds (Si—O) and silicon-hydrogen bonds (Si—H) so that hydroxyl group in the silanol-based material may be replaced with oxygen or hydrogen in the silanol-based material, thereby changing the silanol-based material into silicon oxide.

When the silicon oxide layer is formed using the polysilazane-based material, the polysilazane-based material includes bonds of silicon-nitrogen (Si—N), silicon-hydrogen (Si—H) and nitrogen-hydrogen (N—H) such that the bonds in the polysilazane-based material may be substituted for silicon-oxygen bonds (Si—O) by providing oxygen. Thus, the polysilazane-based material may be changed into silicon oxide.

In an example embodiment of the present invention, the coated SOG may be thermally treated at a temperature above about 400° C. for about 10 minutes to about 120 minutes. In the heat treatment process for the coated SOG, however, the temperature may vary in accordance with a SOG composition.

In case that the silicon oxide layer is formed using the polysilazane-based material including the silicon-nitrogen bonds, silicon-hydrogen bonds and nitrogen-hydrogen bonds, the polysilazane-based material may be thermally treated under an oxygen atmosphere so that the bonds described above in the polysilazane-based material are replaced with the silicon-oxygen bonds, thereby forming the silicon oxide layer on the first insulation layer 108. The oxygen atmosphere may be successfully prepared using a water vapor, an oxygen gas or a combination thereof.

When the silicon oxide layer is formed using the silanol-based material or the siloxane-based material, the silanol-based material or the siloxane-based material includes the silicon-oxygen bonds so that the bonds described above in the silanol-based material or the siloxane-based material may not be substituted for additional silicon-oxygen bonds. Thus, the silanol-based material or the siloxane-based material may be thermally treated under an atmosphere including an oxygen gas, a hydrogen gas or an inactive gas. The inactive gas may include a nitrogen gas, an argon gas, a helium gas, etc. Alternatively, the silanol-based material or the siloxane-based material may be thermally treated under a vacuum atmosphere.

In an example embodiment of the present invention, the silicon oxide layer (i.e., the second insulation layer) may be formed on the first insulation layer 108 through two heat treatment processes. Here, the heat processes described above may be continuously performed on the coated SOG. Alternatively, the two heat processes may be carried out by a predetermined interval.

As described above, the second insulation layer is formed on the first insulation layer 108 using SOG by the spin coating process so that the second insulation layer may effectively fill up the trench 106 without generating the void or the seam therein. However, the coated SOG may not be sufficiently changed into silicon oxide so that the silicon oxide layer may not have a sufficiently dense structure due to pores or impurities generated in the silicon oxide layer. Thus, the silicon oxide layer may not have a desired etching endurance, which would cause the silicon oxide layer to have damages etched from the subsequent etching, cleaning and/or polishing processes.

In an example embodiment of the present invention, the second insulation layer may have a multi-layer structure that includes one silicon oxide film formed by a spin on glass process and another silicon oxide film formed by a CVD process.

The second insulation layer and the first insulation layer 108 are partially removed until the first hard mask pattern 104 is exposed. Thus, a preliminary first insulation layer pattern 108a is formed on the sidewall of the trench 106, and a preliminary second insulation layer pattern 110 is formed on the preliminary first insulation layer pattern 108a to fill up the trench 106. The second insulation layer and the first insulation layer 108 may be partially removed through a CMP process.

Referring to FIG. 5, upper portions of the preliminary first and the preliminary second insulation layer patterns 108a and 110 are etched to form the preliminary isolation layer pattern 111 including a first insulation layer pattern 108b and a second insulation layer pattern 110a. Here, the preliminary isolation layer pattern 111 has an upper face substantially higher than the upper face of the substrate 100 in accordance with partial removals of the preliminary first and preliminary second insulation layer patterns 108a and 110. On the other hand, the upper face of the preliminary isolation layer pattern 111 is substantially lower than an upper face of the mask structure 105. Additionally, the preliminary isolation layer pattern 111 has a height, which is formed substantially higher than a desired height of the floating gate 118b.

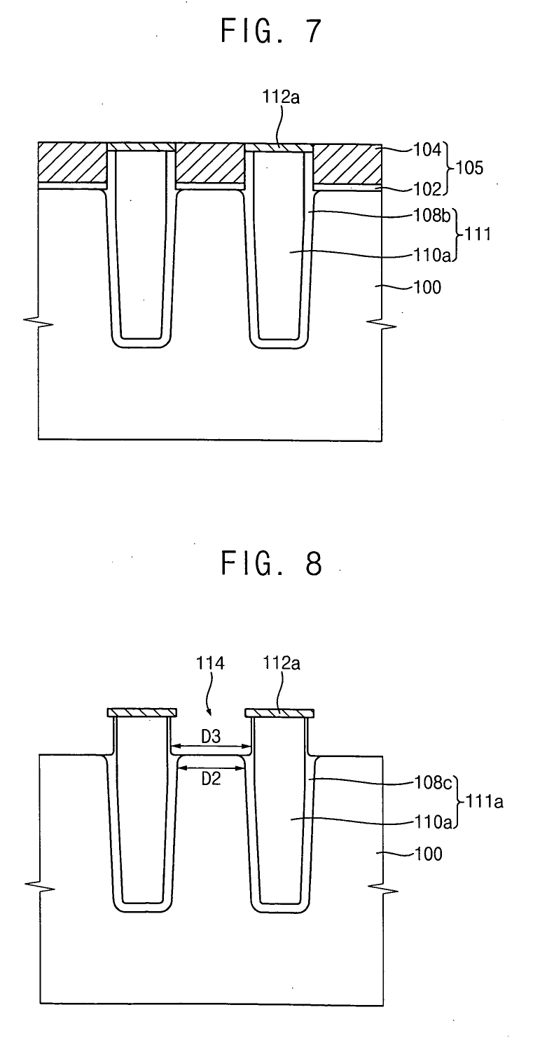

After forming the preliminary isolation layer pattern 111, a first opening 113 is formed on the preliminary isolation layer pattern 111 between the mask structures 105. The first opening 113 may have a depth substantially the same as etched amounts of the preliminary first and the preliminary second insulation layer patterns 108a and 110. However, it should be noted in this context that the terms “depth” and “etched amounts” are not necessarily synonymous one with another. A capping layer pattern 112a (see FIG. 7) is positioned in the first opening 113 (not shown). Hence, the first opening 113 may have a depth substantially greater than a desired thickness of the capping layer pattern 112a. When the capping layer pattern 112a has a thickness below about 30 Å, the capping layer pattern 112a may not protect the isolation layer pattern 111a in a subsequent polishing process. Thus, it is necessary for the first opening 113 to have a depth above about 50 Å in order to ensure a formation of the capping layer pattern 112a that protects the isolation layer pattern 111a.

In an example embodiment of the present invention, the preliminary isolation layer pattern 111 may have the upper face lower than an upper face of the first hard mask pattern 104 by about 50 Å to about 2,500 Å. For example, the upper face of the first hard mask pattern 104 may be higher than the upper face of the preliminary isolation layer pattern 111 by about 300 Å.

Referring to FIG. 6, a capping layer 112 is continuously formed on the mask structure 105 and on the preliminary isolation layer pattern 111. The capping layer 112 may be formed using a material that is hardly etched in subsequent wet etching processes for etching silicon oxide and silicon nitride. For example, the capping layer 112 may be formed using doped polysilicon or undoped polysilicon. In one example embodiment of the present invention, the capping layer 112 may be formed on the preliminary isolation layer pattern 111 to partially fill up the first opening 113. In another example embodiment of the present invention, the capping layer 112 may be formed on the preliminary isolation layer pattern 111 to completely fill up the first opening 113.

When the capping layer 113 has a thickness below about 50 Å, the capping layer pattern 112a may not effectively protect the preliminary isolation layer pattern 111 in the subsequent processes. However, the capping layer pattern 112a may not be properly polished in the subsequent polishing process when the capping layer 112 has a thickness above about 5,000 Å. Hence, the capping layer 112 may have a thickness in a range of about 50 Å to about 5,000 Å.

Referring to FIG. 7, a portion of the capping layer 112 positioned on the mask structure 105 is selectively removed to form the capping layer 112a on the preliminary isolation layer pattern 111. The capping layer pattern 112a may be formed through a polishing process such as a CMP process. While forming the capping layer pattern 112a, the mast structure 105 may be slightly removed so that the mask structure 105 may have a reduced height.

Referring to FIG. 8, the first hard mask pattern 104 is removed from the pad oxide layer pattern 102. The first hard mask pattern 104 may be removed by a wet etching process. Then, the pad oxide layer pattern 102 is removed from the substrate 100 together with a portion on a sidewall of the preliminary isolation layer pattern 111 making contact with the mask structure 105. The pad oxide layer pattern 102 and the portion on the sidewall of the preliminary isolation layer pattern 111 may be etched by a wet etching process. Therefore, the isolation layer pattern 111a is formed together with the second opening 114. The isolation layer pattern 111a includes a remaining first insulation layer pattern 108c and a second insulation layer pattern 110a.

Hereinafter, an exemplary process adapted to the formation of the isolation layer pattern 111a will be described in some additional detail.

Before removing the first hard mask pattern 104, oxides and/or particles are removed from the first hard mask pattern 104 using an etching solution containing diluted hydrogen fluoride (HF) solution. Then, the first hard mask pattern 104 is removed from the pad oxide layer pattern 102 using an etching solution that includes a phosphoric acid (H₃PO₄) solution.

The pad oxide layer pattern 102 is removed from the substrate 100 using an etching solution that includes an ammonia (NH₄OH) solution, a hydrogen peroxide (H₂O₂) solution and water such as a standard cleaning 1 (SC-1) solution or a standard cleaning 2 (SC-2) solution.

When the pad oxide layer pattern 102 is removed, the portion on the sidewall of the isolation layer pattern 111a is etched because the preliminary first insulation layer pattern 108b includes oxide. Hence, the second opening 114 has a width D3 substantially greater than a width D2 of the active region of the substrate 100. In some example embodiments of the present invention, the width D3 of the second opening 114 may be wider than the width D2 of the active region by about 70 Å to about 150 Å.

When a crystalline structure of the second insulation layer pattern 110a is not denser than that of the first insulation layer pattern 108c, the second insulation layer pattern 110a may be etched together with the pad oxide layer pattern 102. However, the remaining first insulation layer pattern 108c may effectively protect the second insulation layer pattern 110a in the etching process for removing the pad oxide layer pattern 102. That is, the second insulation layer pattern 110a is not exposed after removing the pad oxide layer pattern 102 because the remaining first insulation layer pattern 108c covers the second insulation layer pattern 110a.

In some example embodiments of the present invention, the second insulation layer pattern 110a may not be substantially etched because the first insulation layer pattern 108c covers the second insulation layer pattern 110a during the etching process for removing the pad oxide layer pattern 102.

When the first hard mask pattern 104 and the pad oxide layer pattern 102 are removed, the thickness of the isolation layer pattern 111a may not be reduced because the capping layer pattern 112a is formed on the isolation layer pattern 111a. For example, the thickness of the isolation layer pattern 111a may not decrease even in case that several etching processes for etching the first hard mask pattern 104 and the pad oxide layer pattern 102 may be carried out. Therefore, the isolation layer pattern 111a may have a desired thickness for advantageously forming the floating gate 118b. Additionally, the isolation layer pattern 111a may have a uniform thickness because the capping layer pattern 112a effectively protects the isolation layer pattern 111a.

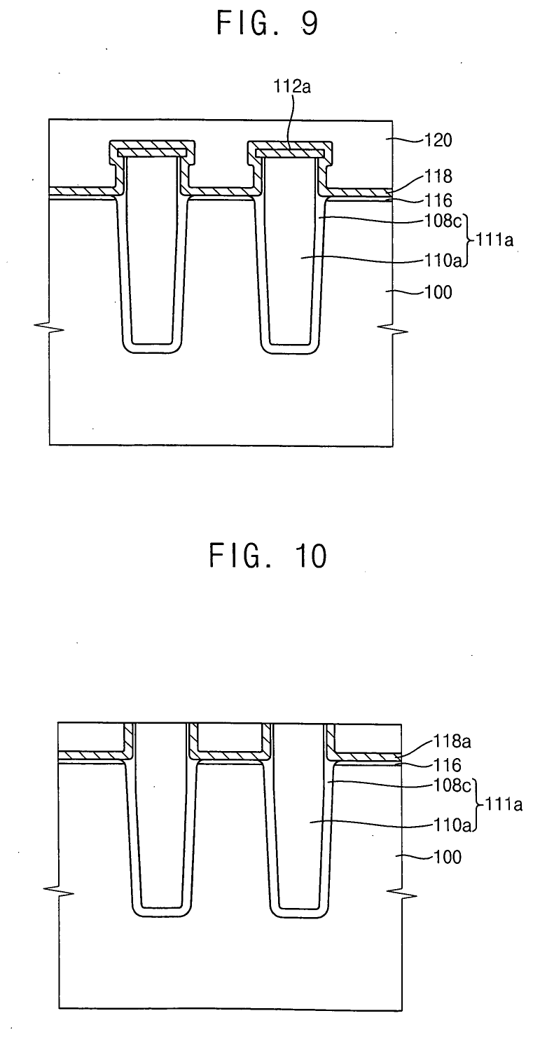

Referring to FIG. 9, a tunnel oxide layer 116 is formed on a portion of the substrate 100 exposed by the second opening 114 (see FIG. 8). The tunnel oxide layer 116 may be formed using an oxide such as silicon oxide. Additionally, the tunnel oxide layer 116 may be formed by a thermal oxidation process.

A first conductive layer 118 is continuously formed on a sidewall of the second opening 114, on the tunnel oxide layer 116 and on the capping layer pattern 112a. The first conductive layer 118 will be patterned to form the floating gate 118b on the tunnel oxide layer 116. The first conductive layer 118 may be formed using polysilicon doped with impurities by a low pressure chemical vapor deposition (LPCVD) process. The impurities in the first conductive layer 118 may be doped by a POCl3 diffusion process, an ion implantation process, an in-situ doping process, etc.

A sacrificial layer 120 is formed on the first conductive layer 118 to completely fill up the second opening 114. The sacrificial layer 120 may be formed using silicon oxide that effectively fills up the second opening 114.

Referring to FIG. 10, the sacrificial layer 120, the first conductive layer 118 and the capping layer pattern 112a are partially removed until the isolation layer pattern 111a is exposed, thereby forming a floating gate layer 118a on the tunnel oxide layer 116. Additionally, the floating gate layer 118a is formed on the sidewall of the isolation layer pattern 111a. Thus, the floating gate layer 118a may have a cross-section of a U shape. The floating gate layer 118a may be formed through a CMP process.

Since the isolation layer pattern 111a has the uniform thickness having the desired height, the floating gate layer 118a may also have a uniform thickness having a desired height. That is, the floating gate layer 118a is formed using the isolation layer pattern 111a as a mold pattern so that the floating gate 118b (see FIG. 11) formed on the sidewall of the isolation layer pattern 111a and on the tunnel oxide layer may have a sufficient height and the uniform thickness over the substrate 100.

Referring to FIG. 11, a remaining sacrificial layer 120 in the second opening 114 is removed from the floating gate layer 118a. When the sacrificial layer 120 (see FIG. 9) is completely removed from the floating gate layer 118a, a recess is generated on the isolation layer pattern 111a whereas the tunnel oxide layer 116 is not exposed.

A dielectric layer is formed on the floating gate layer 118a. The dielectric layer may be formed using silicon oxide or silicon nitride. Alternatively, the dielectric layer may have a multi-layer structure including one or more silicon oxide films and one or more silicon nitride films. Furthermore, the dielectric layer may be formed using a metal oxide having a high dielectric constant such as hafnium oxide, zirconium oxide, tantalum oxide, etc.

In the illustrated embodiment, a second conductive layer is formed on the dielectric layer. The second conductive layer may be formed using doped polysilicon or metal.

After a second hard mask pattern (not shown) is formed on the second conductive layer, the second conductive layer, the dielectric layer and the floating gate layer 118a are partially etched to form a gate structure on the substrate 100. The gate structure includes the floating gate 118b, a dielectric layer pattern 122 and a control gate 124 sequentially formed over the substrate 100. The second hard mask pattern may have a line shape that extends along a second direction substantially perpendicular to the first direction.

According to some example embodiments of the present invention, an isolation layer pattern having a desired height and a uniform thickness may be formed on a substrate to thereby improve electrical characteristics of a non-volatile semiconductor device. Additionally, a floating gate of the non-volatile semiconductor device may have a sufficient height and a uniform thickness when the floating gate is formed using the isolation layer pattern as a mold pattern through an SAP process.

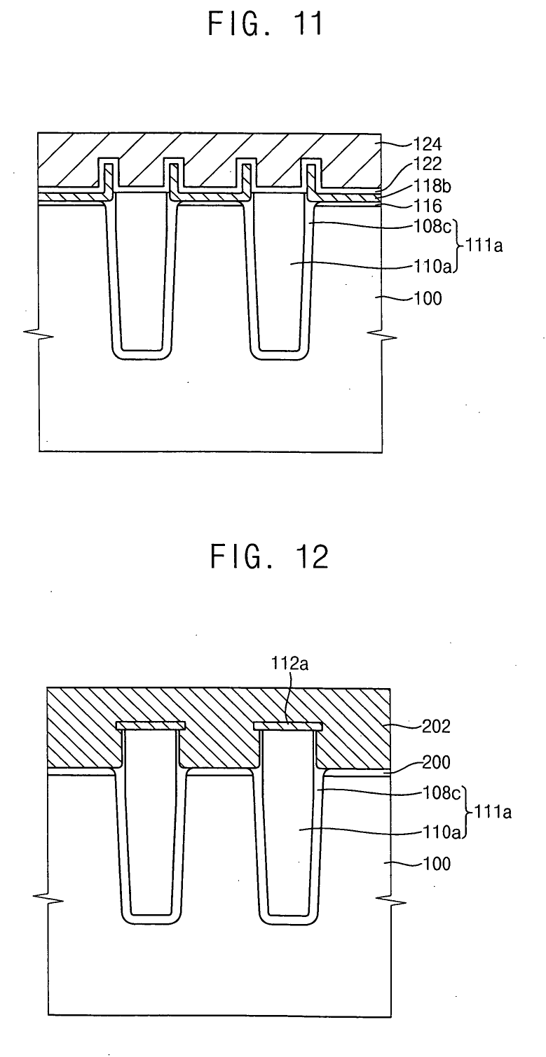

FIGS. 12 to 14 are cross-sectional views illustrating a method of manufacturing a non-volatile semiconductor device in accordance with example embodiments of the present invention. The method described in FIGS. 12 to 14 may be substantially the same as the method described with reference to FIGS. 1 to 11 except for processes adapted to the formation of a floating gate 202a.

An isolation layer pattern 111a is formed on a substrate 100 to fill up a trench. The isolation layer pattern 111a includes a first insulation layer pattern 108c and a second insulation layer pattern 110a. A capping layer pattern 112a is formed on the isolation layer pattern 111a. A second opening 114 exposing a portion of the substrate 100 is formed adjacent to the isolation layer pattern 111a.

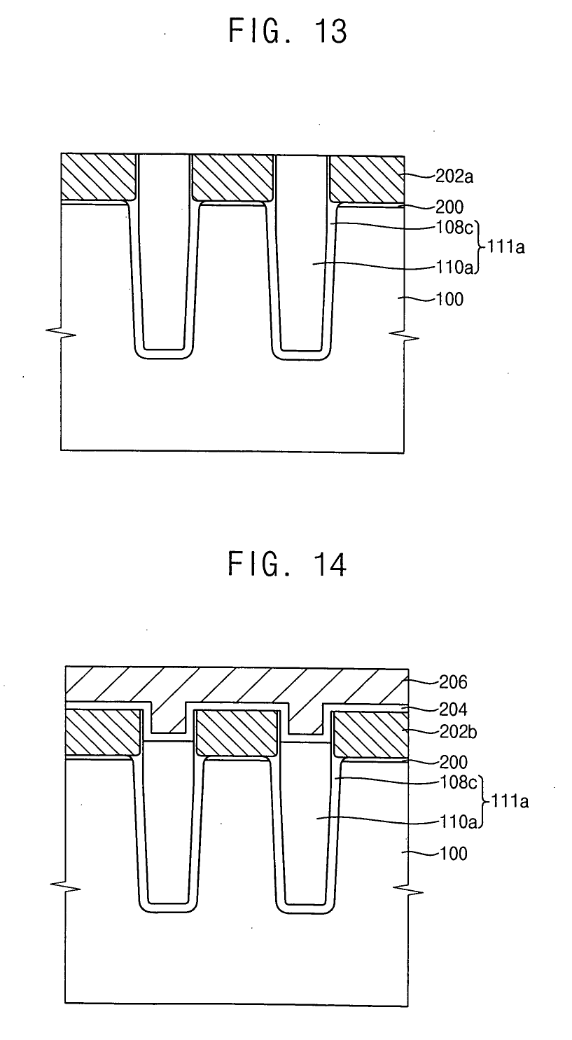

Referring to FIG. 12, a tunnel oxide layer 200 (see e.g., FIG. 13) is formed on the exposed portion of the substrate 100. The tunnel oxide layer 200 may include silicon oxide prepared by performing a thermal oxidation process on the upper portion of the substrate 100.

A first conductive layer 202 is formed on the tunnel oxide layer 200 (see FIG. 13) and on the capping layer pattern 112a to completely fill up the opening 114. The first conductive layer 202 will be patterned to form the floating gate 202a (see FIG. 13). The first conductive layer 202 may be formed using polysilicon doped with impurities by an LPCVD process. Here, the impurities may be doped into the first conductive layer 202 by a POCl3 diffusion process, an ion implantation process, an in-situ doping process, etc.

In one example embodiment of the present invention, the first conductive layer 202 may be formed through one LPCVD process.

In another example embodiment of the present invention, the first conductive layer 202 may be formed through two LPCVD processes so as to prevent a void or a seam from being generated in the first conductive layer 202. Particularly, the first conductive layer 202 may be formed by sequentially performing a first LPCVD process, a partial wet etching process and a second LPCVD process.

Referring to FIG. 13, portions of the first conductive layer 202 and the capping layer pattern 112a are removed to form a floating gate layer 202a on the tunnel oxide layer 200. The floating gate layer 202a may be formed by a CMP process. The floating gate layer 202a may have a line shape that extends along a first direction over the substrate 100.

Referring to FIG. 14, an upper portion of the isolation layer pattern 111a is removed. Although the isolation layer pattern 111a is partially removed, the tunnel oxide layer 202 is not exposed whereas a sidewall of the floating gate layer 202a is partially exposed.

A dielectric layer is formed on the isolation layer pattern 111a and on the floating gate layer 202a. The dielectric layer is also formed on the exposed sidewall of the floating gate layer 202a. The dielectric layer may be formed using silicon oxide, silicon nitride or metal oxide. Alternatively, the dielectric layer may have a multi-layer structure that includes one or more silicon oxide films and silicon nitride films.

In the illustrated embodiments, a second conductive layer is formed on the dielectric layer. The second conductive layer may be formed using doped polysilicon or metal.

A hard mask pattern (not shown) is formed on the second conductive layer. The mask pattern may have a line shape that extends along a second direction substantially perpendicular to the first direction over the substrate 100.

The second conductive layer, the dielectric layer and the floating gate layer 202a are partially etched using the hard mask pattern as an etching mask. Thus, a gate structure having the floating gate 202b, a dielectric layer pattern 204 and a control gate 206 is formed on the substrate 100.

According to example embodiments of the present invention, a non-volatile semiconductor device may be provided with enhanced electrical characteristics due to the presences of an isolation layer pattern having a desired height and a uniform thickness. Additionally, a floating gate in the non-volatile semiconductor device may be provided with a desired height and a uniform thickness due to the use of an isolation layer pattern as a mold pattern during an SAP process. Therefore, the non-volatile semiconductor device including the floating gate may have improved operational characteristics and reliability.

The foregoing is illustrative of the present invention and is not to be construed as limiting thereof. Although embodiments of the present invention have been described, those skilled in the art will readily appreciate that many modifications to the example embodiments are possible without materially departing from the novel teachings and advantages of the present invention. Accordingly, all such modifications are intended to be included within the scope of the present invention as defined in the claims.

What is claimed is:

1. A method of manufacturing a non-volatile semiconductor device, comprising:
forming a mask structure including a pad oxide layer pattern and a hard mask pattern sequentially formed on a substrate;
selectively etching the substrate using the mask structure as an etching mask to form a trench in the substrate;
forming a preliminary isolation layer pattern on the substrate to fill the trench, wherein the preliminary isolation layer pattern has an upper face substantially lower than an upper face of the mask structure;
forming a capping layer pattern on the preliminary isolation layer pattern;
forming an opening and an isolation layer pattern by removing the mask structure and a portion on a sidewall of the preliminary isolation layer pattern making contact with the mask structure;
forming a tunnel oxide layer on a portion of the substrate exposed by the opening; and
forming a floating gate on the tunnel oxide layer and a sidewall of the isolation layer pattern.

2. The method of claim 1, wherein the upper face of the preliminary isolation layer pattern is substantially higher than an upper face of the substrate.

3. The method of claim 1, wherein the preliminary isolation layer pattern comprises a first insulation layer pattern and a second insulation layer pattern wherein the first insulation layer pattern prevents the sidewall of the preliminary isolation layer pattern from being excessively etched, and the second insulation layer pattern isolates the floating gate from an adjacent floating gate.

4. The method of claim 3, wherein forming the preliminary isolation layer pattern comprises:
continuously forming a first insulation layer on a sidewall and a bottom of the trench and on the mask structure;
forming a second insulation layer on the first insulation layer to fill up the trench;
forming a preliminary first insulation layer pattern and a preliminary second insulation layer pattern by partially removing the first and the second insulation layers until the mask structure is exposed; and
forming the first insulation layer pattern on the sidewall and the bottom of the trench and forming the second insulation layer pattern on the first insulation layer pattern by removing upper portions of the preliminary first and the preliminary second insulation layer patterns.

5. The method of claim 4, wherein the first insulation layer is formed using a material that has an etching rate substantially lower than an etching rate of a material in the second insulation layer.

6. The method of claim 4, wherein the first insulation layer is formed using silicon oxide prepared by a thermal chemical vapor deposition process or by a high density plasma chemical vapor deposition process.

7. The method of claim 6, wherein the second insulation layer is formed using silicon oxide prepared by a spin on glass process.

8. The method of claim 4, wherein the first insulation layer is selectively etched when the portion on the sidewall of the preliminary isolation layer is removed to form the isolation layer pattern.

9. The method of claim 1, wherein the upper face of the mask structure is higher than the upper face of the preliminary isolation layer pattern by about 100 Å to about 2,500 Å.

10. The method of claim 1, wherein forming the capping layer pattern comprises:
forming a capping layer on the mask structure and on the preliminary isolation layer pattern; and
selectively removing a portion of the capping layer positioned on the mask structure.

11. The method of claim 10, wherein the capping layer is selectively removed by a chemical mechanical polishing (CMP) process.

12. The method of claim 10, wherein the capping layer has a thickness of about 50 Å to about 5,000 Å.

13. The method of claim 1, wherein the capping layer pattern is formed using polysilicon.

14. The method of claim 1, wherein forming the floating gate comprises:
continuously forming a first conductive layer on a sidewall of the opening, on the tunnel oxide layer and on the capping layer pattern;
forming a sacrificial layer on the first conductive layer to fill up the opening; and
forming the floating gate by partially removing the sacrificial layer, the first conductive layer and the capping layer pattern until the isolation layer pattern is exposed.

15. The method of claim 14, wherein the first conductive layer is formed using polysilicon doped with impurities by a chemical vapor deposition process.

16. The method of claim 14, further comprising:
removing the sacrificial layer and a portion of the isolation layer pattern until the floating gate is exposed;
forming a dielectric layer on the floating gate; and
forming a control gate on the dielectric layer.

17. The method of claim 1, wherein forming the floating gate comprises:
forming a first conductive layer on the tunnel oxide layer to fill up the opening: and
forming the floating gate by partially removing the first conductive layer and the capping layer pattern until the isolation layer pattern is exposed.

18. The method of claim 17, further comprising:
partially removing the isolation layer pattern until a sidewall of the floating gate is exposed;
forming a dielectric layer on the floating gate; and
forming a control gate on the dielectric layer.
